(19) United States
(12) Patent Application Publication
(10) Pub. No.: US 2026/0104295 A1
(43) Pub. Date: Apr. 16, 2026

(54) CIRCUITRY FOR ALLOWING MULTIPLE SENSORS ON A SEMICONDUCTOR DIE TO SHARE A COMMON SENSOR PAD

(71) Applicant: Wolfspeed, Inc., Durham, NC (US)

(72) Inventor: Thomas Harrington, Durham, NC (US)

(21) Appl. No.: 18/915,457

(22) Filed: Oct. 15, 2024

(51) Int. Cl. G01K 7/01

(52) U.S. Cl. CPC G01K 7/01

(57) ABSTRACT

A semiconductor die includes a sensor pad, first sensor circuitry electrically connected to the sensor pad, and isolation circuitry coupled between the first sensor circuitry and the sensor pad. The isolation circuitry may be configured to selectively block an electrical current from flowing from the sensor pad to the first sensor circuitry. The semiconductor die may further include second sensor circuitry electrically connected to the sensor pad. The first sensor circuitry may include a current sensor, and the second sensor circuitry may include a temperature sensor.

### FIELD

The present disclosure relates generally to semiconductor devices, and, more particularly, to a semiconductor die including multiple on-chip sensors.

### BACKGROUND

Semiconductor devices are ubiquitous in electronic devices and systems. Wide bandgap semiconductor material systems, such as gallium nitride (GaN) and silicon carbide (SiC), are increasingly utilized in semiconductor devices to push the boundaries of device performance in areas such as switching speed, power handling capability, and heat dissipation. Examples include individual devices such as metal-oxide-semiconductor field-effect transistors (MOSFETs), insulated gate bipolar transistors (IGBTs), Schottky barrier diodes, PIN diodes, high electron mobility transistors (HEMTs), and integrated circuits such as monolithic microwave integrated circuits (MMICs) that include one or more individual devices.

Modern power devices frequently incorporate one or more on-chip sensors to measure certain operating characteristics of the device. Common on-chip sensors include, for example, temperature sensors and current sensors. Each on-chip sensor generally requires the addition of at least one bonding pad (i.e., sensor pad) so that the sensor can be measured electrically and accessed externally. Every sensor pad that is added to a power semiconductor die typically results in the loss of active device area (i.e., device area that contributes to current conduction and therefore power switching). Therefore, adding multiple sensor pads for corresponding multiple on-chip sensors results in a significant loss of active device area in the power semiconductor die.

### SUMMARY

The present inventive concept, as manifested in embodiments disclosed herein, is directed to semiconductor devices. A semiconductor device may include a device active region that implements the intended functionality of the semiconductor device and multiple sensors (e.g., a current sensor and a temperature sensor) for measuring corresponding operating parameters (e.g., current and temperature) of the device active region, where at least some of the sensors share a common sensor pad. For example, a current sensor may be configured to mirror (i.e., provide a scaled replicate of) a load current in the device active region during operation of the semiconductor device for purposes of measuring the load current in the device active region. Likewise, a temperature sensor may be configured to measure an operating temperature of the device active region. In example embodiments, the semiconductor device may comprise a power MOSFET with multiple on-chip sensors (e.g., current sensor and temperature sensor). The single sensor pad is shared by the multiple on-chip sensors for providing external electrical access to the on-chip sensors. Isolation circuitry may be electrically interposed between at least one of the on-chip sensors and the shared sensor pad to prevent current or voltage intended for measuring one on-chip sensor from impacting the other on-chip sensor(s) in the semiconductor device. The use of a single shared sensor pad to access multiple on-chip sensors, as opposed to employing a separate sensor pad for each on-chip sensor, may result in a significant increase in useable active device area, particularly in semiconductor devices that include a single top side metallization layer.

In accordance with an embodiment of the present disclosure, a semiconductor die includes a sensor pad, first sensor circuitry electrically connected to the sensor pad, and isolation circuitry coupled between the first sensor circuitry and the sensor pad. The isolation circuitry may be configured to selectively block an electrical current from flowing from the sensor pad to the first sensor circuitry. The semiconductor die may further include second sensor circuitry electrically connected to the sensor pad. The first sensor circuitry may include a current sensor, and the second sensor circuitry may include a temperature sensor.

In accordance with another embodiment of the present disclosure, a semiconductor die includes a power transistor device, first sensor circuitry, second sensor circuitry, and isolation circuitry coupled between the first sensor circuitry and the second sensor circuitry. The isolation circuitry is configured to block an electrical current from flowing to the first sensor circuitry. The first sensor circuitry may include a current sensor, and the second sensor circuitry may include a temperature sensor.

In accordance with yet another embodiment of the present disclosure, a semiconductor die includes a first MOSFET having a first source pad, a second MOSFET having a second source pad, and a temperature sensor electrically coupled to the second source pad. The semiconductor die may further include isolation circuitry coupled between the second MOSFET and the second source pad. The isolation circuitry may include a blocking diode having a cathode connected to the second source pad and an anode connected to the second MOSFET.

In accordance with an embodiment of the present disclosure, a method for performing temperature sensing includes: providing a temperature sensor, a current sensor and an isolation circuit in a semiconductor die, the temperature sensor coupled to a sensor pad, and the current sensor coupled to the sensor pad through the isolation circuit; turning off the current sensor; providing a current to the temperature sensor through the sensor pad, the isolation circuit configured to prevent the current from flowing to the current sensor; and measuring a voltage at the sensor pad generated by the temperature sensor, the measured voltage correlated to a temperature of the semiconductor die.

In accordance with another embodiment of the present disclosure, a method for performing current sensing includes: providing a temperature sensor, a current sensor and an isolation circuit in a semiconductor die, the temperature sensor coupled to a sensor pad in the semiconductor die, and the current sensor coupled to the sensor pad through the isolation circuit; turning on the current sensor; applying a voltage to the sensor pad to turn on the isolation circuit; and measuring a first current generated by the current sensor at the sensor pad, the first current correlated to a second current flowing through a transistor device in the semiconductor die.

Aspects of the present inventive concept can provide substantial beneficial technical effects. By way of example only and without limitation, techniques according to embodiments of the present disclosure may provide one or more of the following advantages, among other benefits:
reduces the loss of active device area by sharing a single sensor pad among multiple on-chip sensors;
provides isolation between multiple on-chip sensors without significantly affecting breakdown voltage in the semiconductor device;
easily integrates with existing fabrication processes without requiring additional masks or increasing device fabrication complexity.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the inventive concept and are incorporated in and constitute a part of this application, are presented by way of example only and without limitation, wherein like reference numerals (when used) indicate corresponding elements throughout the several views, and wherein:

FIG. 1 illustrates a schematic top view layout of an example semiconductor device including an on-chip current sensor;

FIG. 2 is a schematic diagram depicting an equivalent circuit for an implementation of an example current sensor for a MOSFET which may be utilized in conjunction with embodiments of the present disclosure;

FIG. 3 is a schematic diagram depicting a semiconductor device including an on-chip current sensor and an on-chip temperature sensor;

FIGS. 4A and 4B are schematic diagrams each depicting at least a portion of an example transistor semiconductor die including multiple sensors sharing a single sensor pad, according to illustrative embodiments of the inventive concept;

FIG. 5A is a flow chart depicting an illustrative method for performing a temperature measurement operation using the combined sensor pad arrangement shown in FIG. 4, according to one or more embodiments of the inventive concept;

FIG. 5B is a flow chart depicting an illustrative method for performing a current sensing operation using the combined sensor pad arrangement shown in FIG. 4, according to one or more embodiments of the inventive concept;

FIG. 6 is a schematic diagram depicting at least a portion of an example transistor semiconductor die including multiple sensors sharing a single sensor pad, according to one or more embodiments of the inventive concept;

FIG. 7 is a schematic cross-sectional view depicting a portion of the transistor semiconductor die shown in FIG. 4, according to one embodiment of the present inventive concept;

FIG. 8 is a schematic cross-sectional view depicting a portion of the transistor semiconductor die shown in FIG. 4, according to another embodiment of the present inventive concept; and

FIG. 9 is a schematic cross-sectional view depicting at least a portion of a current sensor blocking diode fabricated using a junction-isolated silicon carbide diode, according to one or more embodiments of the inventive concept.

In the plan view(s) described above, various layers such as upper metal and insulating/passivation layers may be removed to illustrate other underlying regions, layers and/or structures of the device. This does not imply, however, that the removed layers are omitted in the completed device.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in embodiments disclosed herein, are described in the context of semiconductor die including at least one power semiconductor device integrated with multiple on-chip sensors that are configured to measure certain operating conditions of an integrated power device (e.g., power MOSFET). At least two of the on-chip sensors may share a single sensor pad for providing external access to the on-chip sensors. The semiconductor die may also comprise isolation circuitry that is interposed between the at least two on-chip sensors.

Semiconductor devices according to embodiments of the present invention are described below using a power MOSFET as an example semiconductor device. A power MOSFET is typically fabricated using a large number of unit cells. Each unit cell may comprise an individual MOSFET, and the unit cells are electrically connected together in parallel with one another; that is, with their gates connected together, their drains connected together, and their sources connected together.

Power MOSFETs sometimes include on-chip current sensors, that are used to measure the current flowing through the power MOSFET when it is switched on (the on-state current). An on-chip current sensor may be implemented by adding an on-chip resistor electrically in series along the current path, and then sensing the voltage drop across the resistor to measure the on-state current flow. Unfortunately, this results in a large amount of unwanted power dissipation/loss in the resistor. To reduce this loss, it is known to provide a current sensing MOSFET in which one or a relatively small number of the MOSFET cells are connected to the power MOSFET in a current mirror configuration. As is well known in the art, a current mirror is a circuit which functions to generate a copy of a current flowing into or out of an input terminal of the circuit (i.e., a reference current) by replicating the current in an output terminal of the circuit irrespective of the load conditions. The replicated output current is typically scaled by a prescribed factor or ratio so that it is much smaller than the on-state current, and hence the power dissipation in the resistor may be reduced by about the prescribed factor or ratio.

The current sensing MOSFET typically includes a separate source terminal, referred to as a sense pad or terminal. The current sensing MOSFET also typically comprises a plurality of unit cells that each comprise an individual MOSFET, where the unit cells are electrically connected together in parallel, although in some cases the current sensing MOSFET may be implemented as a single unit cell. An external current sensing resistor can be connected between the sense pad and ground (or another voltage source), and may be on the semiconductor die or implemented off the semiconductor die (i.e., off-chip). Since only a predetermined small fraction of the total load current of the power MOSFET passes through the resistor, power dissipation in the current sensing resistor is relatively small.

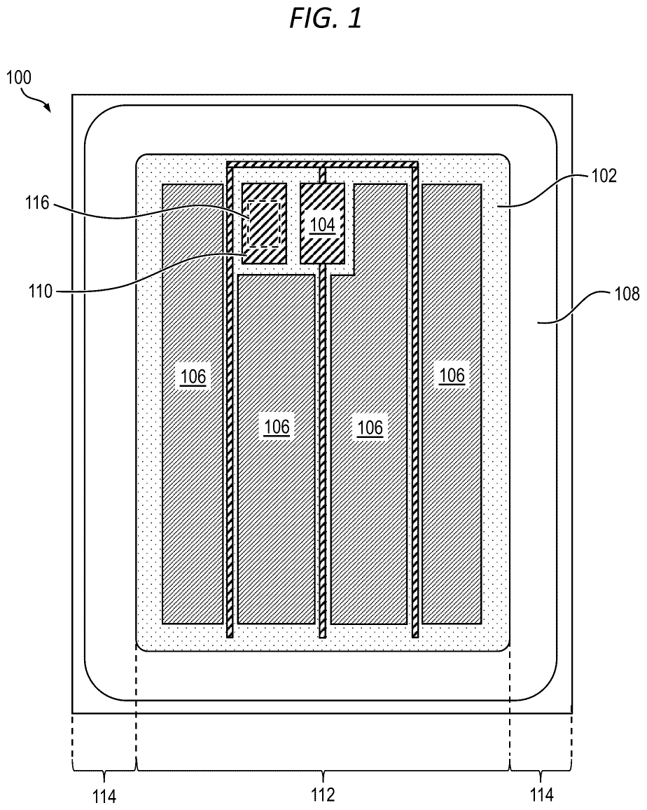

FIG. 1 illustrates a schematic top view layout of an example semiconductor device 100 including an on-chip current sensor. By way of illustration only, the semiconductor device 100 is a vertical MOSFET device comprising a passivation structure 102 formed with openings for a gate contact 104 and one or more source contacts 106. While a MOSFET device is illustrated, the principles of the present disclosure may be applicable to other semiconductor devices as well, for example, other MOSFETs, diodes, Schottky diodes, junction barrier Schottky (JBS) diodes, PIN diodes, and insulated gate bipolar transistors (IGBTs), among other devices. Thus, while the semiconductor device 100 is illustrated and described herein as being a MOSFET, it will be appreciated that in other embodiments it may be any other applicable semiconductor device, such as the example semiconductor devices listed above. The semiconductor device 100 may embody wide bandgap semiconductor devices, for example, silicon carbide (SiC)-based devices, and still further 4H-SiC based devices.

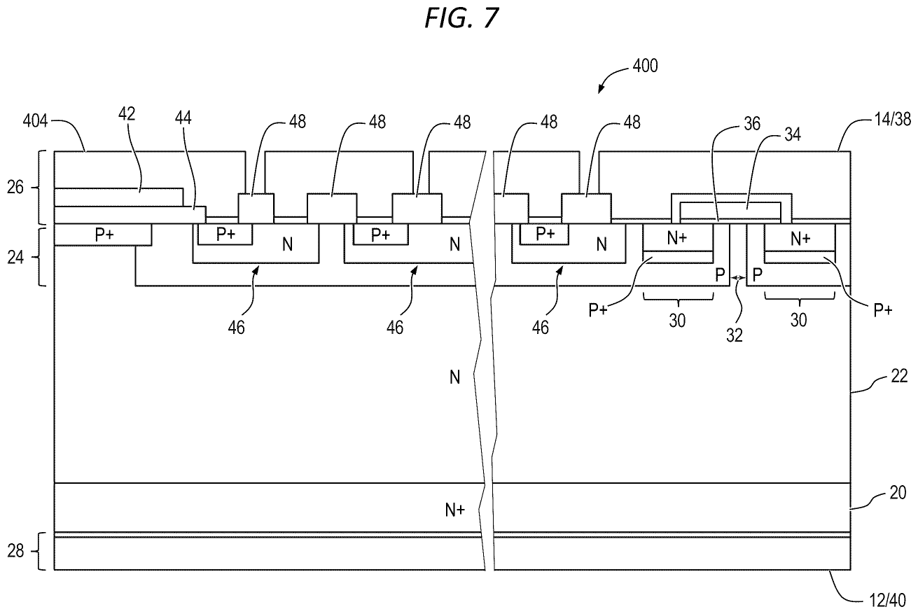

The MOSFET 100 of FIG. 1 includes a wide bandgap semiconductor layer structure (not visible in FIG. 1, but see FIG. 7). The MOSFET 100 is a vertical power MOSFET in which a drain contact (not explicitly shown) is located on a back side of the wide bandgap semiconductor layer structure, while the gate contact 104 and the source contacts 106 are on a front side of the wide bandgap semiconductor layer structure. The drain contact, the gate contact 104 and the source contacts 106 may be provided as surfaces for coupling the power MOSFET 100 to external circuitry. In the case of an IGBT, the drain contact may be a collector contact, the source contacts 106 may be emitter contacts, and the gate contact 104 may be a gate (or control) contact.

An edge termination region 108 may be arranged along an outer perimeter of the power MOSFET 100 in the wide bandgap semiconductor layer structure. The edge termination region 108 may be arranged to reduce a concentration of an electric field at the edges of the power MOSFET 100 in order to improve the performance thereof. For example, the edge termination region 108 may increase a breakdown voltage of the power MOSFET 100 and/or decrease a leakage current of the power MOSFET 100. By way of example, the edge termination region 108 may include one or more guard rings, a junction termination extension (JTE), and/or combinations thereof.

The power MOSFET 100 may further comprise a sensor contact or pad 110. The sensor pad 110 may provide a contact for any type of sensor that is at least partially incorporated within the power MOSFET 100, for example, a temperature sensor, a strain sensor, or a current sensor. In the case of a current sensor, a current sensor active region 116 that is electrically connected to the sensor pad 110 may occupy an area of the power MOSFET 100 that would otherwise (i.e., if no on-chip current sensor was provided) form part of a device active region 112 for the power MOSFET 100. In the example of FIG. 1, the portion of the power MOSFET 100 underneath the source contacts 106 may comprise the device active region 112 while the portion of the power MOSFET 100 underneath the gate contact 104 and the edge termination region 108 may each be part of an inactive region 114 of the power MOSFET 100. The portion of the power MOSFET 100 underneath the sensor contact 110 may comprise the sensor active region 116 and may also include a region that is part of the inactive region 114, since the sensor pad 110 is typically larger, and often much larger, than the sensor active region 116.

The sensor pad 110 provides a contact area that may be electrically connected, for example, by a wire bond or other electrical connection, to one or more external circuit elements for sensor monitoring. The sensor pad 110 may be electrically connected to source regions of the unit cells in the sensor active region 116 of the power MOSFET 100. In the case of a current sensor, the sensor pad 110 may also be electrically connected to one or more external circuit elements for monitoring a portion of the load current that flows in the sensor active region 116 of the power MOSFET 100 that is electrically coupled to the sensor pad 110. The current flowing in the sensor active region 116 of the power MOSFET 100 may mirror (at a predetermined ratio) the current flowing in the device active region 112 of the power MOSFET 100 and hence may be used to measure the current flowing in the device active region 112 of the power MOSFET 100.

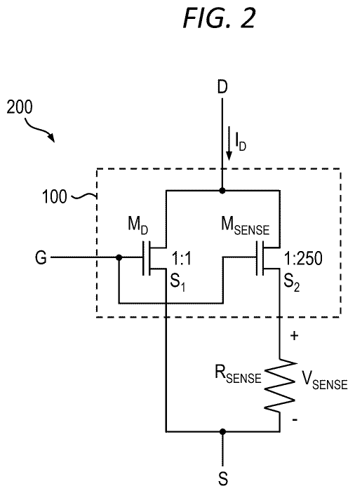

FIG. 2 is a schematic diagram depicting an equivalent circuit 200 for an implementation of an example current sensor for a MOSFET which may be utilized in conjunction with embodiments of the present disclosure. A dashed-line box in FIG. 2 represents the power MOSFET 100 of FIG. 1 with the remaining portion of the equivalent circuit 200 being external to the power MOSFET 100 (i.e., the remaining portion of the first equivalent circuit 200 is off-chip). Referring to FIGS. 1 and 2, by forming the sensor contact (e.g., sensor pad 110) as a separate source contact, the power MOSFET 100 thereby includes a device MOSFET (M_{D}) and a sensing MOSFET (M_{SENSE}) that are connected to a common drain (D) and a common gate (G). Source connections for each of the MOSFETs (M_{D} and M_{SENSE}) are coupled in parallel so that the current flow, I_{D}, from the common drain may be split across the MOSFETs (M_{D} and M_{SENSE}). The ratio of current flow from the source (S₁) of the device MOSFET (M_{D}) to the current flow from the source (S₂) of the sensing MOSFET (M_{SENSE}) corresponds to a ratio of the area of the power MOSFET 100 that is occupied by the device active region 112 to the area of the power MOSFET 100 that is occupied by the sensor active region 116.

By way of example only, FIG. 2 illustrates an embodiment where the ratio of current flow is selected to be 1:250 based on the relative areas of the device MOSFET M_{D} and the sensing MOSFET M_{SENSE}. Using this ratio of current flow, when one amp (A) of current flows through the device active region 112 of power MOSFET 100, four milliamps (mA) of current (i.e., 1/250) will flow from the source path of the sensing MOSFET (M_{SENSE}), through a sense resistor, R_{SENSE}, connected between the source (S₂) of the sensing MOSFET M_{SENSE} and a common source terminal, S. By arranging the sense resistor R_{SENSE} along the source path from the sensing MOSFET M_{SENSE}, a corresponding sense voltage, V_{SENSE}, may be measured and correlated to the load current of the device MOSFET M_{D}, according to the ratio described above. Other current sensing configurations are possible with the arrangement of the power MOSFET 100.

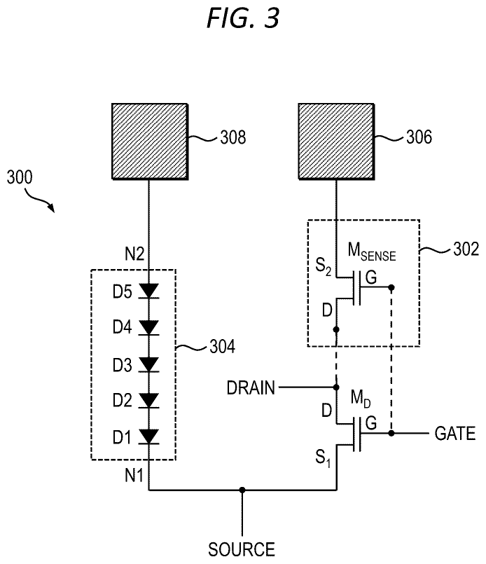

FIG. 3 is a schematic diagram depicting a semiconductor device 300 including an on-chip current sensor 302 and an on-chip temperature sensor 304. The on-chip current sensor 302 and the on-chip temperature sensor 304 are operatively coupled to a power MOSFET, which may be referred to herein as a device MOSFET (M_{D}), although other device types may be similarly employed (e.g., diodes, Schottky diodes, JBS diodes, PIN diodes, IGBTs, etc.), as previously stated. The on-chip current sensor 302 may be implemented in a manner consistent with the on-chip current sensor shown in FIGS. 1 and 2, although embodiments are not limited thereto. For example, the on-chip current sensor 302 may comprise a sensing MOSFET (M_{SENSE}) that is connected to the device MOSFET M_{D} in a common drain (D) and a common gate (G) configuration; that is, the drains of the device MOSFET M_{D} and the sensing MOSFET M_{SENSE} are electrically connected together, and the gates of the device MOSFET M_{D} and the sensing MOSFET M_{SENSE} are electrically connected together. The connection between the drains of the device MOSFET M_{D} and the sensing MOSFET M_{SENSE} and the connection between the gates of the device MOSFET M_{D} and the sensing MOSFET M_{SENSE} are illustrated as dotted lines to indicate that these connections may be made anywhere on the chip.

A source (S₂) of the sensing MOSFET M_{SENSE} is connected to a current sensor pad 306. The current sensor pad 306, which may be a bonding pad, provides access to the on-chip current sensor 302 so that the current flowing in the device MOSFET M_{D} can be externally measured. A source (S₁) of the device MOSFET M_{D} may be electrically connected to a first node N1 of the on-chip temperature sensor 304. A second node N2 of the on-chip temperature sensor 304 is connected to a separate temperature sensor pad 308.

The on-chip temperature sensor 304 may be implemented as one or more temperature sensing diodes, D1, D2, D3, D4 and D5, electrically connected together in series. Specifically, a cathode of a first diode (D1) is connected to the source of the device MOSFET M_{D}, an anode of the first diode D1 is connected to a cathode of a second diode (D2), an anode of the second diode D2 is connected to a cathode of a third diode (D3), an anode of the third diode D3 is connected to a cathode of a fourth diode (D4), an anode of the fourth diode D4 is connected to a cathode of a fifth diode (D5), and an anode of the fifth diode D5 is connected to the temperature sensor pad 308. Although five temperature sensing diodes are shown in FIG. 3, it is to be appreciated that the number of diodes may be changed based on the total forward voltage drop required for a particular application, with each diode providing a forward voltage drop of, for example, about 0.7 volt.

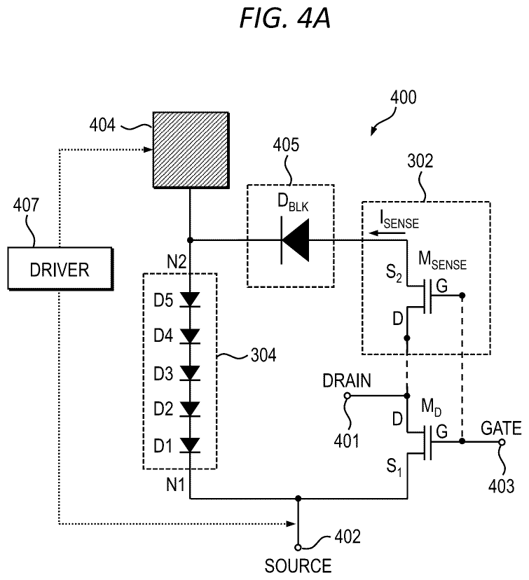

As previously stated, each sensor pad 306, 308 consumes a substantial amount of area in the semiconductor device 300 which could otherwise be used as active device area. In accordance with aspects of the inventive concept, a single sensor pad is used to provide external access to multiple on-chip sensors, thereby significantly reducing the amount of active device area required. FIGS. 4A and 4B are schematic diagrams depicting at least a portion of example transistor semiconductor die 400 and 450, respectively, including multiple sensors sharing a single sensor pad, according to illustrative embodiments of the inventive concept.

Referring to FIG. 4A, the transistor semiconductor die 400 includes a first current terminal 401 a second current terminal 402, and a control terminal 403. A semiconductor structure defined between the first current terminal 401, the second current terminal 402, and the control terminal 403 forms a transistor device M_{D} such that a resistance between the first current terminal 401 and the second current terminal 402 is based on a control signal GATE provided at the control terminal 403. As shown in FIG. 4, the transistor device M_{D} in this embodiment is a power device MOSFET. Accordingly, the first current terminal 401 is a drain terminal, the second current terminal 402 is a source terminal, and the control terminal 403 is a gate terminal.

However, the principles of the present disclosure apply equally to any transistor device such as, for example, diodes, Schottky diodes, JBS diodes, PIN diodes, IGBTs, etc.

The transistor semiconductor die 400 further includes a first sensor, which may be an on-chip current sensor 302, and a second sensor, which may be an on-chip temperature sensor 304. Although only two types of on-chip sensors are described herein, it is to be understood that the inventive concept is not limited to temperature and current sensors, but rather contemplates that other types of on-chip sensors may be similarly employed (e.g., humidity sensor, pressure sensor, etc.). It will also be appreciated that the semiconductor device 400 may include more than two sensors. The on-chip current sensor 302 and the on-chip temperature sensor 304 are operatively coupled to the device MOSFET M_{D} and may be configured to measure the current in the device MOSFET M_{D} and the temperature of the device MOSFET M_{D}, respectively.

As previously explained, the device MOSFET M_{D} may be fabricated using a large number of unit cells that are electrically connected together in parallel with one another; each unit cell may comprise an individual MOSFET. A power handling capability of the device MOSFET M_{D} may be increased (or decreased) by accordingly increasing (or decreasing) the number of unit cells forming the device MOSFET M_{D} and/or the size of the unit cells. In one or more embodiments, the sensing MOSFET M_{SENSE} in the on-chip current sensor 302 may be fabricated using a subset of unit cells forming the device MOSFET M_{D}, although this subset of unit cells would not be included in the count of the plurality of unit cells forming the device MOSFET M_{D}. In other words, the unit cells forming the sensing MOSFET M_{SENSE} are isolated (source-wise) from the unit cells forming the device MOSFET M_{D}. The unit cells forming the sensing MOSFET M_{SENSE} may be in a region of the layout which is physically isolated (e.g., by a P-type isolation region) from the unit cells forming the device MOSFET M_{D}.

The on-chip current sensor 302 may be implemented in a manner consistent with the on-chip current sensor shown in FIGS. 1 and 2, although embodiments are not limited thereto. For example, the on-chip current sensor 302 may comprise a sensing MOSFET (M_{SENSE}) that is connected to the device MOSFET M_{D} in a common drain and common gate configuration. The connection between the drains of the device MOSFET M_{D} and the sensing MOSFET M_{SENSE} and the connection between the gates of the device MOSFET M_{D} and the sensing MOSFET M_{SENSE} are illustrated in FIG. 4 as dotted lines to represent that these connections may be made anywhere on the chip. In one or more embodiments, each of the device MOSFET M_{D} and sensor MOSFET M_{SENSE} are implemented as a vertical MOSFET device, although embodiments are not limited thereto.

The on-chip temperature sensor 304, like the on-chip temperature sensor 304 shown in FIG. 3, may be implemented using one or more temperature sensing diodes, D1, D2, D3, D4 and D5, electrically connected in a series configuration. Specifically, a cathode of a first diode (D1) is connected to the source of the device MOSFET M_{D}, an anode of the first diode D1 is connected to a cathode of a second diode (D2), an anode of the second diode D2 is connected to a cathode of a third diode (D3), an anode of the third diode D3 is connected to a cathode of a fourth diode (D4), an anode of the fourth diode D4 is connected to a cathode of a fifth diode (D5), and an anode of the fifth diode D5 is connected to a combined sensor pad 404. Each of the temperature sensing diodes D1 through D5 may have a prescribed negative temperature coefficient (e.g., about −2 mV/° C. for silicon diodes), such that the diode has a forward voltage (Vf) that decreases with increasing temperature (and vice versa). Although five temperature sensing diodes are shown in FIG. 4, it is to be appreciated that the number of diodes may be adjusted (either higher or lower) based on the total forward voltage drop required for a given application; each diode provides a forward voltage drop of about 0.7 volt (V) if the temperature sensing diodes are implemented in a polysilicon layer.

Referring to FIG. 4B, the transistor semiconductor die 450 may be configured to reduce switching noise in the on-chip temperature sensor 304, according to some embodiments. The semiconductor die 450 may be substantially similar to the illustrative transistor semiconductor die 400 shown in FIG. 4A, except that the cathode of the first diode D1 in the on-chip temperature sensor 304 may be electrically disconnected from the source of the device MOSFET M_{D} such that the cathode of the first diode D1 at node N1 is connected to a separate temperature sense pad 406.

An external driver circuit 407, connected between the combined sensor pad 404 and the temperature sense pad 406, may be configured to force a positive current into the on-chip temperature sensor 304 for obtaining a die-level temperature measurement. In some applications, the external driver circuit 407 may prefer to have node N1 electrically disconnected from the source of the device MOSFET M_{D} for noise reasons; that is, the second current terminal 402, which in this example may be a source of the device MOSFET M_{D}, may be subjected to switching noise injected from the device MOSFET M_{D}, depending on when the external driver circuit 407 measures the voltage across the temperature sensing diodes D1 through D5 when node N1 is connected to the second current terminal 402. With node N1 connected to a separate pad 406, the external driver circuit 407 is isolated from the device MOSFET M_{D} and can therefore evaluate the temperature sensing diodes D1 through D5 even while the device MOSFET M_{D} is switching. Even in this embodiment where a separate temperature sense pad 406 is employed, the transistor semiconductor die 450 maintains the benefit of reducing the total number of pads (e.g., from three pads to two pads) since a single combined sensor pad 404 is used for the multiple on-chip sensors.

For the transistor semiconductor die 450 which uses a separate temperature sense pad 406, the external driver circuit 407 may include a switch 408 on a low side of the external driver circuit 407 (i.e., the connection to the cathode of the first temperature sense diode D1 at node N1) to electrically connect the temperature sense pad 406 to the second current terminal 402 while measuring current, and to disconnect the temperature sense pad 406 from the second current terminal 402 while measuring temperature. In the case where current is being measured and the switch 408 is configured to electrically connect the temperature sense pad 406 to the second current terminal 402, the electrical connection to the second current terminal 402 provides the correct electrical reference for the sensing MOSFET M_{SENSE}, while the electrical connection to the temperature sense pad 406 provides the correct electrical reference for keeping the temperature sensing diodes D1 through D5 turned off.

Referring again to FIG. 4A, in the transistor semiconductor die 400, the on-chip current sensor 302 and the on-chip temperature sensor 304 share a single combined sensor pad 404. In order to prevent current intended for measuring a response of the on-chip temperature sensor 304 from flowing into the on-chip current sensor 302, the transistor semiconductor die 400 includes an isolation circuit 405 connected between the on-chip current sensor 302 and the combined sensor pad 404. In one or more embodiments, the isolation circuit 405 may comprise a current sensor blocking diode (D_{BLK}). An anode of the current sensor blocking diode D_{BLK} is connected to a source (S₂) of the sensing MOSFET M_{SENSE}, and a cathode of the current sensor blocking diode D_{BLK} is connected to a second node N2 that is in between the combined sensor pad 404 and the current sensing diodes D1 through D5.

In one or more embodiments, the current sensor blocking diode D_{BLK} is configured to have sufficient current-carrying capability—which may be achieved, for example, by appropriately configuring a physical size for the diode (i.e., an area of the diode P-N junction)—to be able to conduct a sense current I_{SENSE} generated by the on-chip current sensor 302 (e.g., from the sensor MOSFET M_{SENSE}) without the current sensor blocking diode D_{BLK} itself limiting the sense current I_{SENSE}. By way of example only and without limitation, if the sense current I_{SENSE} generated by the sensor MOSFET M_{SENSE} is designed to be 1 mA and the current sensor blocking diode D_{BLK} current density is 1 μA/μm, then the blocking diode D_{BLK} should be sized having a junction width of 1000 μm

$$( W = \frac{1}{J} ,$$

where W is the diode P-N junction width, I is diode current, and J is diode current density).

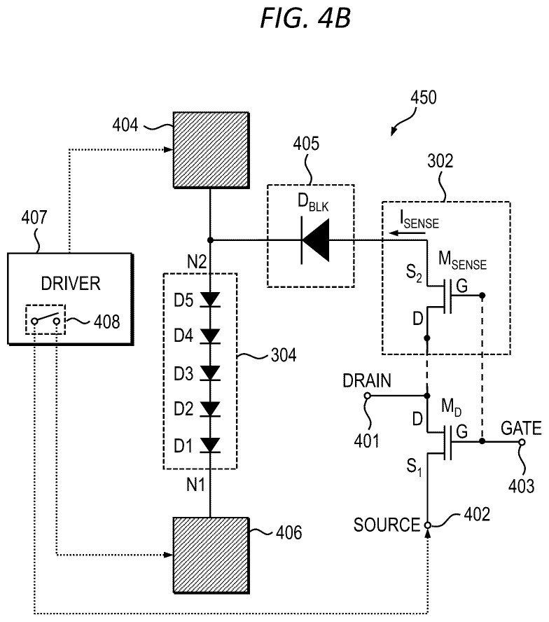

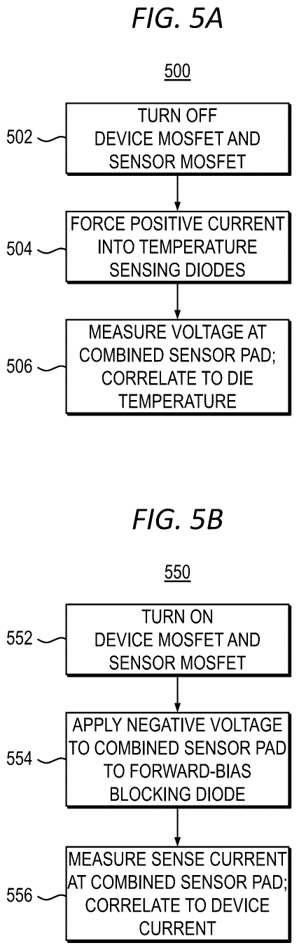

FIG. 5A is a block diagram depicting an illustrative method 500 for performing a temperature measurement operation using the combined sensor pad arrangement shown in FIG. 4, according to one or more embodiments. Referring to FIGS. 4 and 5A, during the temperature measurement operation according to some embodiments, the sensor MOSFET M_{SENSE} in the on-chip current sensor 302 and the device MOSFET M_{D} may be turned off in step 502, such as, for example, by applying an appropriate control voltage to the control terminal 403 (i.e., gate) of the device MOSFET M_{D} (e.g., a voltage at or below the source voltage of the device MOSFET M_{D}). It is to be appreciated that in some embodiments where a separate low-side temperature sense pad is employed (e.g., the temperature sense pad 406 shown in FIG. 4B), it may not be necessary to turn off the device MOSFET M_{D}, and in this scenario step 502 may be omitted.

In step 504, the external driver circuit 407, which may be connected between the second current terminal 402 (i.e., source) of the device MOSFET M_{D} and the combined sensor pad 404, is configured to force a positive current (e.g., tens of microamps to tens of milliamps) into the on-chip temperature sensor 304, which flows through the stack of temperature sensing diodes D1 through D5. The positive current generated by the external driver circuit 407 should be selected to forward-bias the series temperature sensing diodes D1 through D5 so that a forward voltage drop may be measured at the combined sensor pad 404 in step 506.

Since each of the temperature sensing diodes D1 through D5 has a negative temperature coefficient that causes its forward voltage (Vf) to decrease with increasing temperature, and vice versa, the measured voltage at the combined sensor pad 404 will be correlated to a temperature of the temperature sensing diodes D1 through D5 (step 506), thereby allowing for a die-level temperature measurement to be obtained externally to the transistor semiconductor device 400. The isolation circuit 405 is configured to prevent the externally forced positive current from flowing into the on-chip current sensor 302.

FIG. 5B is a block diagram depicting an illustrative method 550 for performing a current sensing operation using the combined sensor pad arrangement shown in FIG. 4, according to one or more embodiments. Referring to FIGS. 4 and 5B, during the current sensing operation according to some embodiments, the sensor MOSFET M_{SENSE} in the on-chip current sensor 302 and the device MOSFET M_{D} may be turned on in step 552, such as, for example, by applying an appropriate control voltage to the gate of the device MOSFET M_{D} (e.g., at or above a threshold voltage of the device MOSFET M_{D}), so that a current flows from the drain to the source in each of these devices M_{D} and M_{SENSE}. In step 554, the external driver circuit 407, which may be connected between the source of the device MOSFET M_{D} and the combined sensor pad 404, applies a negative voltage (e.g., about −1 V) to the combined sensor pad 404 to bias the current sensor blocking diode D_{BLK} in the isolation circuit 405 into a forward current direction (i.e., forward-biased). This allows the sense current I_{SENSE} from the sensor MOSFET M_{SENSE} to flow through the blocking diode D_{BLK} to the combined sensor pad 404 where the sense current I_{SENSE} may be measured by the external driver circuit 407 in step 556. Since the sense current I_{SENSE} will be a known fraction of the full current in the device MOSFET M_{D}, the overall current flowing in the device MOSFET M_{D} can be determined and monitored (step 556).

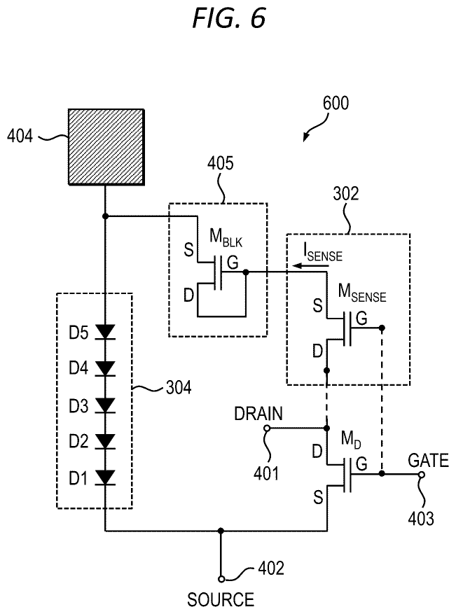

FIG. 6 is a schematic diagram depicting at least a portion of an example transistor semiconductor die 600 including multiple sensors sharing a single sensor pad, according to one or more embodiments of the inventive concept. The transistor semiconductor die 600 may be configured in a manner consistent with the illustrative transistor semiconductor die 400 shown in FIG. 4, except for implementation of the blocking circuit 405. Referring to FIG. 6, the transistor semiconductor die 600 includes a first current terminal 401 a second current terminal 402, and a control terminal 403. A semiconductor structure between the first current terminal 401, the second current terminal 402, and the control terminal 403 forms a transistor device M_{D} such that a resistance between the first current terminal 401 and the second current terminal 402 is based on a control signal GATE provided at the control terminal 403. As shown in FIG. 6, the transistor device M_{D} in this embodiment is a power device MOSFET. Accordingly, the first current terminal 401 is a drain terminal, the second current terminal 402 is a source terminal, and the control terminal 403 is a gate terminal. However, the principles of the present disclosure apply equally to any transistor device such as, for example, diodes, Schottky diodes, JBS diodes, PIN diodes, IGBTs, etc.

The transistor semiconductor die 600 comprises multiple on-chip sensors, including an on-chip current sensor 302 and an on-chip temperature sensor 304, although embodiments are not limited thereto. The on-chip current sensor 302 and the on-chip temperature sensor 304 are operatively coupled to the device MOSFET M_{D}. The transistor semiconductor die 600 further includes an isolation circuit 405 connected between a combined sensor pad 404 and the on-chip current sensor 302.

In one or more embodiments, the isolation circuit 405 comprises a blocking MOSFET M_{BLK} connected in a diode configuration. Specifically, a drain and gate of the blocking MOSFET M_{BLK} are connected to the source of the sensor MOSFET M_{SENSE} in the on-chip current sensor 302, and a source of the blocking MOSFET M_{BLK} is electrically connected to the combined sensor pad 404. Connected in this manner, the blocking MOSFET M_{BLK} operates in essentially the same manner as the blocking diode D_{BLK} (see FIG. 4) to prevent current generated by the external driver circuit (e.g., 407 in FIGS. 4A and 4B) for measuring a response of the on-chip temperature sensor 304 from being forced into the on-chip current sensor 302.

In one or more embodiments, the blocking MOSFET M_{BLK} may be implemented using a lateral MOSFET device, if a lateral MOSFET device is available and is electrically isolated from the vertical MOSFETs M_{D} and M_{SENSE}. The lateral MOSFET device may be implemented, for example, in the wide bandgap semiconductor layer structure, on the wide bandgap semiconductor layer structure, or off-die. The blocking MOSFET M_{BLK} should be configured having sufficient current-carrying capability—which may be achieved, for example, by appropriately selecting a physical size (e.g., channel width/channel length ratio of the MOSFET) for the blocking MOSFET device—to be able to conduct the sense current I_{SENSE} generated in the on-chip current sensor 302 (e.g., from the sensor MOSFET M_{SENSE}) without the blocking MOSFET M_{BLK} itself limiting the sense current I_{SENSE}.

The temperature sensing diodes (D1 through D5 in FIG. 4) constituting the on-chip temperature sensor (304 in FIG. 4) and the current sensor blocking diode (D_{BLK} in FIG. 4) may be fabricated, for example, in the wide bandgap semiconductor layer structure or in a separate polysilicon layer with N+ and P+ doping regions defined by masking and ion implantation.

FIG. 7 is a schematic cross-sectional view depicting a portion of the transistor semiconductor die 400 shown in FIG. 4, according to an embodiment in which the temperature sensing diodes (D1 through D5 in FIG. 4) are implemented in the wide bandgap semiconductor layer structure. Referring to FIG. 7, the transistor semiconductor die 400 includes a substrate 20, a drift layer 22 on the substrate 20, a number of implants 24 in the drift layer 22, a top metallization layer 26, and a bottom metallization layer 28. On the right side of the transistor semiconductor die 400 the device MOSFET M_{D} (see FIG. 4) is provided as a vertical MOSFET including a pair of junction implants 30 in the drift layer 22 such that the junction implants 30 are separated by a junction field-effect transistor (JFET) gap 32. The substrate 20, the drift layer 22, and the implants 24, 30 in the drift layer 22 comprise a wide bandgap semiconductor layer structure of the transistor semiconductor die 400. A gate contact 34 on top of a gate oxide layer 36 extends between the junction implants 30 on a surface of the drift layer 22 opposite the substrate 20. A source contact 38 (which may also be the second current terminal 402 in FIG. 4) also contacts each one of the junction implants 30 on the surface of the drift layer 22 opposite the substrate. A drain contact 40 (which may also be the first current terminal 401 in FIG. 4) is on the substrate 20 opposite the drift layer 22. The source contact 38 is provided by a portion of the top metallization layer 26. The drain contact 40 is provided by the bottom metallization layer 28.

In the example embodiment of FIG. 7, the device includes a single top metallization layer (meaning that the top metallization layer is formed using a single masking step) that is used to form the gate contact 34, the source contacts 38 and the sensor pad 404. This single top metallization layer may include multiple different metal layers that are all formed using the single mask, such as one or more of an ohmic layer, adhesion slayers, barrier layers and/or bulk metal layers.

On the left side of the transistor semiconductor die 400, the combined sensor pad 404 (see FIG. 4) is provided by a portion of the top metallization layer 26. A number of P-N junctions 46 are formed in the drift layer 22 and hence in the wide bandgap semiconductor layer structure. For clarity purposes, only two P-N junctions are shown in FIG. 7 that implement diodes D1 and D2, although it will be appreciated that diodes D3 through D5 are implemented in the same manner. Each one of the P-N junctions 46 forms one of the temperature sensing diodes D1 through D5 described above in conjunction with FIG. 4. The top metallization layer 26 is appropriately patterned to form connections between a cathode of a first one of the temperature sensing diodes D1 and the source contact 38, between the anode and cathode of each pair of adjacent temperature sensing diodes, and between the anode of a last one of the temperature sensing diodes D5 and the combined sensor pad 404. An intermetal dielectric layer 48 may electrically insulate different portions of the top metallization layer 26 to form the desired connection pattern.

While only one unit cell of the device MOSFET M_{D} is shown in FIG. 7, the device MOSFET M_{D} may comprise any number of cells coupled together to provide a desired forward current rating of the transistor semiconductor die 400, as previously stated. Moreover, while the temperature sensing diodes are shown adjacent one another in the drift layer 22 in FIG. 7, the temperature sensing diodes D1 through D5 may be distributed in any suitable manner in the transistor semiconductor die 400. For example, the temperature sensing diodes D1 through D5 may be distributed between different cells of the device MOSFET M_{D} in a pattern in order to reduce the total active area devoted to the temperature sensing diodes D1 through D5. In general, the temperature sensing diodes D1 through D5 will consume very little area when compared to the device MOSFET M_{D} and thus will have a minimal impact on the total active area of the transistor semiconductor die 400.

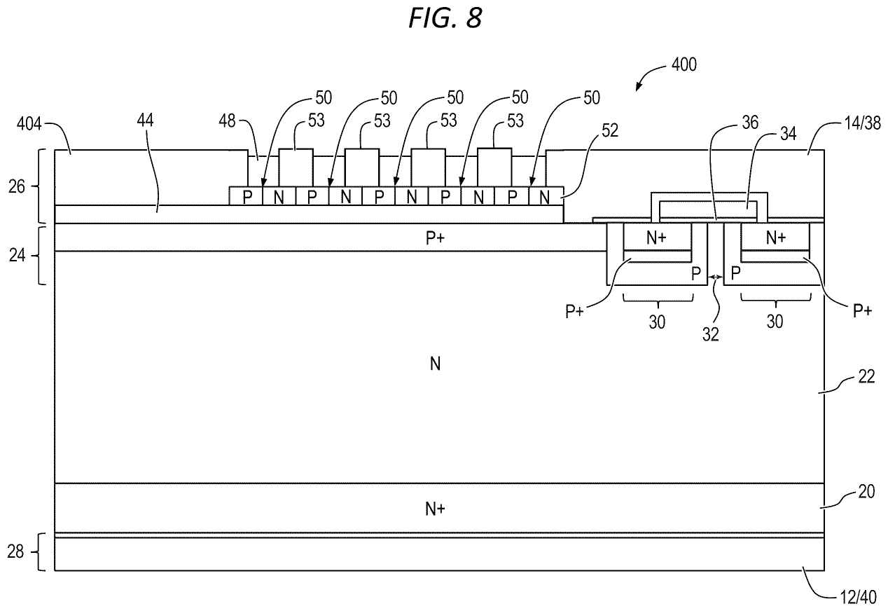

FIG. 8 is a schematic cross-sectional view depicting a portion of the transistor semiconductor die 400 shown in FIG. 4, according to another embodiment of the present inventive concept. Referring to FIG. 8, the transistor semiconductor die 400 is substantially similar to that shown in FIG. 7, except that the temperature sensing diodes D1 through D5 are formed as a number of P-N junctions 50 in an additional semiconductor layer 52 (e.g., a polysilicon layer) that is provided on the drift layer 22 (with the field oxide layer 44 between the additional semiconductor layer 52 and the drift layer 22 to avoid interaction between the layers). A plurality of conductive (e.g., metal) jumpers 53 may be provided between each pair of adjacent diodes such that the temperature sensing diodes D1 through D5 are coupled in series, anode-to-cathode, between the combined sensor pad 404 and the second current terminal 14 (402 in FIG. 4), wherein a cathode of a first one of the temperature sensing diodes D1 is electrically connected to the second current terminal 14 (i.e., source contact of the device MOSFET M_{D} in FIG. 4) and an anode of a last one of the temperature sensing diodes D5 is electrically connected to the combined sensor pad 404. This is a simple fabrication approach since the polysilicon layer is fully electrically isolated, by dielectric layers above and below the polysilicon layer, so that the polysilicon layer does not react with the power device MOSFET M_{D}.

Although not explicitly shown, the current sensor blocking diode D_{BLK} may also be formed in a manner consistent with the formation of the temperature sensing diodes D1 through D5, although the current sensor blocking diode D_{BLK} will likely be larger in size compared to the temperature sensing diodes D1 through D5 due to the additional current handling requirements of the current sensor blocking diode D_{BLK}. However, the current sensor blocking diode D_{BLK} may alternatively be fabricated within the SiC epitaxial layer, according to one or more embodiments.

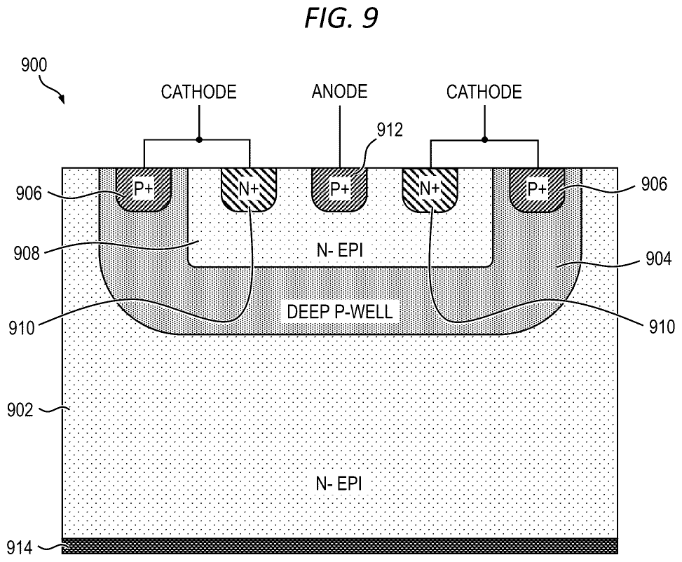

FIG. 9 is a schematic cross-sectional view depicting at least a portion of a current sensor blocking diode (e.g., D_{BLK} shown in FIG. 4) fabricated using a junction-isolated SiC diode, according to one or more embodiments. In the embodiment of FIG. 9, the current sensor blocking diode (e.g., D_{BLK} shown in FIG. 4) is implemented in the wide bandgap semiconductor layer structure. As discussed above, in other embodiments the current sensor blocking diode (e.g., D_{BLK} shown in FIG. 4) may instead by implemented in a separate semiconductor layer (e.g., a polysilicon layer) that is formed, for example on an upper surface of the wide bandgap semiconductor layer structure and isolated therefrom by one or more dielectric layers. Referring to FIG. 9, a current sensor blocking diode 900 is formed in an epitaxial layer 902 comprised of a wide bandgap material, such as, for example silicon carbide (4H-SiC) having a first conductivity type. In one or more embodiments, the epitaxial layer 902 is doped with an N-type dopant at a prescribed doping concentration level (e.g., about 1×10¹⁴-1×10¹⁷ atoms/cm³) to form an N-epitaxial layer, although embodiments are not limited thereto.

The power device MOSFET M_{D} may also be formed in the epitaxial layer 902. In order to prevent charge carriers from a P+/N− epitaxial diode, when forward-biased, from being injected into the power device MOSFET M_{D}, an additional deep well 904 is formed in the epitaxial layer 902. The deep well 904, which has a second conductivity type (e.g., P-type), is formed in the epitaxial layer 902 proximate an upper surface of the epitaxial layer 902. The deep well 904, which may be formed using an implant process (e.g., ion implantation), serves to electrically isolate the power device MOSFET M_{D} in the N-type epitaxial layer 902 from the current sensor blocking diode. The addition of the deep P-well 904 may require increasing a cross-sectional thickness of the epitaxial layer 902 in order to maintain a desired breakdown voltage (BVdss) of the power device MOSFET M_{D}, since the deep P-well 904 is effectively shortening a height of the N-type epitaxial layer 902 under the diode.

One or more first doped regions 906 of the second conductivity type (e.g., P+) may be formed in the deep well 904, proximate an upper surface of the deep well 904. These first doped regions 906 provide electrical contact with the deep well 904. A shallow well 908 having the first conductivity type (e.g., N−) may be formed in the deep well 904 proximate the upper surface of the deep well 904 and between the P+ doped regions 906. The shallow well 908 may be formed using an epitaxial process that is lightly doped with an N-type dopant. In one or more embodiments, the deep well 904 may be formed using a first mask and first implant process, and a second mask and second implant process may be used to form the shallow well 908, which may form an isolated region of the N-type epitaxial layer 902. The deep well 904 may have slightly higher doping level than the lower N-type epitaxial layer 902 in order to override the N-type doping of the epitaxial layer 902, and the shallow well 908 may have a slightly higher doping level than the deep well 904 in order to override the P-type doping of the deep well 904.

A plurality of second doped regions 910 having the first conductivity type (e.g., N+) are formed in the shallow well 908 proximate an upper surface of the shallow well and adjacent to the first doped regions 906. An electrical connection between adjacent first and second doped regions 906, 908 will form a cathode of the current sensor blocking diode 900. A third doped region 912 having the second conductivity type (e.g., P+) may be formed in the shallow well 908 proximate the upper surface of the shallow well 908 and between the second doped regions 910. An electrical connection to the third doped region 912 will form an anode of the current sensor blocking diode 900. An electrode 914 may be formed on a back side of the epitaxial layer 902. This electrode 914 may be a drain terminal of the vertical power device MOSFET M_{D}.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

It will be appreciated that embodiments of the present invention are not limited to the specific devices, circuits, systems and/or methods illustratively shown and described above. Rather, it will become apparent to those skilled in the art given the teachings above that numerous modifications to the embodiments shown are contemplated and are within the scope of the present inventive concept. That is, no limitations with respect to the embodiments shown and described herein are intended or should be inferred. Those skilled in the art will understand the concepts of the present disclosure and will recognize applications of these concepts not particularly addressed herein. It should be understood that these concepts and applications fall within the scope of the present disclosure and the accompanying claims.

As used herein, the term “and/or” includes any and all combinations of one or more of the associated listed items. Furthermore, it will be understood that although ordinal terms, such as first, second, etc., may be used herein to describe various elements, these elements should not be limited by such terms. These terms are merely used to distinguish one element from another and may not necessarily be used to convey any particular order of the elements unless expressly noted. For example, a first element could be termed a second element and similarly, a second element could be termed a first element, without departing from the scope of the present disclosure.

For the purpose of describing and claiming embodiments of the present invention, the term “MOSFET” (metal-oxide-semiconductor field-effect transistor), as used herein, is intended to be construed broadly and to encompass any type of metal-insulator-semiconductor field-effect transistor. The term MOSFET is, for example, intended to encompass semiconductor field-effect transistors that utilize an oxide material as their gate dielectric, as well as those that do not. In addition, despite a reference to the term “metal” in the acronym MOSFET, the term MOSFET is also intended to encompass semiconductor field-effect transistors wherein the gate is formed from a non-metal material such as, for instance, polysilicon.

Although the overall fabrication method and structures formed thereby as described herein are entirely novel, certain individual or intermediate processing steps required to implement a portion or portions of the method(s) according to one or more embodiments of the inventive concept may utilize conventional semiconductor fabrication techniques and/or conventional semiconductor fabrication tooling. These techniques and/or tooling will already be familiar to those having ordinary skill in the relevant art. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are incorporated by reference herein in their entireties. It is emphasized that while some individual processing steps are set forth herein, those steps are merely illustrative and one skilled in the art may be familiar with several equally suitable alternatives that would also fall within the scope of the present disclosure.

It will be understood that when an element such as a layer, region, or structure is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or structure is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below,” “above,” “upper,” “lower,” “top,” “bottom,” “under,” “over,” “horizontal,” “vertical,” etc., as may be used herein, are intended to describe a spatial relationship of one element, layer, or region to another element, layer, or region as illustrated in the figures, rather than an absolute position of the element, layer, or region. It will be understood that these terms and those discussed above are intended to encompass different orientations of the device in addition to the orientation depicted in the figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

The term “surround” (or “surrounding,” “surrounds,” or other like terms) as may be used herein is intended to refer to an element, such as a component, structure, layer or region, that envelops, encircles, encloses, or extends around another element on all sides when the device is viewed in plan view, although breaks or gaps may also be present. Thus, for example, a material layer having voids or openings therein may still “surround” another layer which it encircles. The term “completely surrounds” may be used if no breaks or gaps are present.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Some embodiments are described herein with reference to schematic illustrations. As such, the actual dimensions of the layers and elements can be different, and variations from the shapes of the illustrations as a result, for example, of manufacturing techniques and/or tolerances, are contemplated. For example, a region illustrated or described as square or rectangular may have rounded or curved features, and regions shown as straight lines may have some irregularity. Thus, the regions illustrated in the figures are schematic and their shapes are not intended to illustrate the precise shape of a region of a device and are not intended to limit the scope of the present disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown and referenced herein with common element numbers and as such their descriptions may not be subsequently repeated.

Those skilled in the art will recognize improvements and modifications to the preferred embodiments of the present disclosure. All such improvements and modifications are considered within the scope of the concepts disclosed herein and the claims that follow.

1. A semiconductor die, comprising:
a sensor pad;
first sensor circuitry electrically connected to the sensor pad; and
isolation circuitry coupled between the first sensor circuitry and the sensor pad.

2. The semiconductor die of claim 1, wherein the isolation circuitry is configured to selectively block an electrical current from flowing from the sensor pad to the first sensor circuitry.

3. The semiconductor die of claim 1, further comprising second sensor circuitry electrically connected to the sensor pad.

4. The semiconductor die of claim 3, wherein the second sensor circuitry comprises a temperature sensor.

5. The semiconductor die of claim 4, wherein the temperature sensor comprises at least one diode having a cathode connected to a power transistor device and an anode connected to the sensor pad.

6. The semiconductor die of claim 4, wherein the temperature sensor comprises a plurality of diodes coupled in series such that each adjacent pair of diodes of the plurality of diodes is connected anode-to-cathode, a cathode of a first one of the plurality of diodes is connected to a power transistor device, and an anode of a last one of the plurality of diodes is connected to the sensor pad.

7. The semiconductor die of claim 1, further comprising a power semiconductor device.

8. (canceled)

9. The semiconductor die of claim 7, wherein the first sensor circuitry comprises a current sensor.

10. The semiconductor die of claim 9, wherein the current sensor comprises a current mirror that mirrors a current of the power semiconductor device.

11. The semiconductor die of claim 1, wherein the isolation circuitry comprises a blocking diode, the blocking diode including a cathode connected to the sensor pad and an anode connected to the first sensor circuitry.

12. The semiconductor die of claim 11, wherein the blocking diode is a polysilicon diode comprising an N-type doped region forming the cathode and a P-type doped region forming the anode.

13. The semiconductor die of claim 1, wherein the isolation circuitry comprises a metal-oxide-semiconductor field-effect transistor (MOSFET) having a gate and a drain connected to the first sensor circuitry and having a source connected to the sensor pad.

14. A semiconductor die, comprising:
a power transistor device;
first sensor circuitry;
second sensor circuitry; and
isolation circuitry coupled between the first sensor circuitry and the second sensor circuitry, the isolation circuitry being configured to block an electrical current from flowing to the first sensor circuitry.

15. The semiconductor die of claim 14, wherein the first sensor circuitry comprises a current sensor.

16. The semiconductor die of claim 15, wherein the power transistor device comprises a first MOSFET and the current sensor comprises a second MOSFET, a drain of the second MOSFET connected to a drain of the first MOSFET, a gate of the second MOSFET connected to a gate of the first MOSFET, and a source of the second MOSFET connected to the isolation circuitry.

17. The semiconductor die of claim 16, wherein the second MOSFET is configured to generate a first current that is a prescribed ratio of a second current in the first MOSFET.

18. The semiconductor die of claim 14, wherein the second sensor circuitry comprises a temperature sensor.

19. The semiconductor die of claim 18, wherein the temperature sensor comprises at least one diode having a cathode connected to the power transistor device and an anode connected to the isolation circuitry.

20. The semiconductor die of claim 18, wherein the temperature sensor comprises at least one diode having an anode connected to the isolation circuitry and a cathode connected to a separate pad electrically isolated from the power transistor device.

21. The semiconductor die of claim 18, wherein the temperature sensor comprises a plurality of diodes coupled in series such that each adjacent pair of diodes of the plurality of diodes is connected anode-to-cathode, a cathode of a first one of the plurality of diodes is connected to the power transistor device, and an anode of a last one of the plurality of diodes is connected to the first sensor circuitry.

22. The semiconductor die of claim 14, further comprising a sensor pad electrically connected to the second sensory circuitry and to the isolation circuitry, the sensor pad configured to provide external electrical access to the first sensor circuitry and the second sensor circuitry.

23. The semiconductor die of claim 14, wherein the isolation circuitry comprises a blocking diode, the blocking diode including a cathode connected to the second sensor circuitry and an anode connected to the first sensor circuitry.

24.-28. (canceled)

29. A semiconductor die, comprising:
a first MOSFET having a first source pad;
a second MOSFET having a second source pad; and
a temperature sensor electrically coupled to the second source pad.

30.-41. (canceled)
